(19) United States
(12) Patent Application Publication
(10) Pub. No.: US 2019/0017891 A1
(43) Pub. Date: Jan. 17, 2019

(54) SENSOR AND ELECTRONIC DEVICE

(71) Applicant: KABUSHIKI KAISHA TOSHIBA, Tokyo (JP)

(72) Inventors: Kenji Otsu, Yokohama Kanagawa (JP); Yoshihiko Fuji, Kawasaki Kanagawa (JP); Akiko Yuzawa, Kawasaki Kanagawa (JP); Michiko Hara, Yokohama Kanagawa (JP); Yoshihiro Higashi, Komatsu Ishikawa (JP); Shiori Kaji, Kawasaki Kanagawa (JP); Kazuaki Okamoto, Yokohama Kanagawa (JP); Shotaro Baba, Kawasaki Kanagawa (JP); Tomohiko Nagata, Yokohama Kanagawa (JP)

(73) Assignee: KABUSHIKI KAISHA TOSHIBA, Tokyo (JP)

(21) Appl. No.: 15/908,626

(22) Filed: Feb. 28, 2018

(30) Foreign Application Priority Data
Jul. 12, 2017 (JP) 2017-136521

(51) Int. Cl. G01L 9/00; H01L 41/113; H01L 41/047; H01L 41/053; H01L 41/04

(52) U.S. Cl. CPC G01L 9/0051; H01L 41/1132; G01L 9/008; H01L 41/053; H01L 41/042; H01L 41/0475

(57) ABSTRACT

According to one embodiment, a sensor includes a first film, a first sensor portion, and first to fourth terminals. The first film includes first to second electrode layers, and a piezoelectric layer. The first film is deformable. The first sensor portion is fixed to a portion of the first film. A first direction from the portion of the first film toward the first sensor portion is aligned with a direction from the second electrode layer toward the first electrode layer. The first sensor portion includes first to second sensor conductive layers, first to second magnetic layers, and a first intermediate layer. The first terminal is electrically connected to the first electrode layer. The second terminal is electrically connected to the second electrode layer. The third terminal is electrically connected to the first sensor conductive layer. The fourth terminal is electrically connected to the second sensor conductive layer.

### CROSS-REFERENCE TO RELATED APPLICATIONS

This application is based upon and claims the benefit of priority from Japanese Patent Application No. 2017-136521, filed on Jul. 12, 2017; the entire contents of which are incorporated herein by reference.

### FIELD

Embodiments described herein relate generally to a sensor and an electronic device.

### BACKGROUND

There is a sensor such as a pressure sensor or the like that converts pressure applied from the outside into an electrical signal. It is desirable to increase the sensing precision of the sensor.

### BRIEF DESCRIPTION OF THE DRAWINGS

FIG. 1A to FIG. 1C are schematic views illustrating a sensor according to a first embodiment;

FIG. 2 is a schematic view illustrating characteristics of the sensor according to the first embodiment;

FIG. 3 is a schematic cross-sectional view illustrating the sensor according to the first embodiment;

FIG. 4 is a schematic cross-sectional view illustrating another sensor according to the first embodiment;

FIG. 5 is a schematic cross-sectional view illustrating another sensor according to the first embodiment;

FIG. 6A to FIG. 6C are block diagrams illustrating the sensor according to the first embodiment;

FIG. 7 is a schematic perspective view illustrating a portion of the sensor according to the embodiment;

FIG. 8 is a schematic perspective view illustrating a portion of another sensor according to the embodiment;

FIG. 9 is a schematic perspective view illustrating a portion of another sensor according to the embodiment;

FIG. 10 is a schematic perspective view illustrating a portion of another sensor according to the embodiment;

FIG. 11 is a schematic perspective view illustrating a portion of another sensor according to the embodiment;

FIG. 12 is a schematic perspective view illustrating a portion of another sensor according to the embodiment;

FIG. 13 is a schematic perspective view illustrating a portion of another sensor according to the embodiment;

FIG. 14 is a schematic view illustrating the electronic device according to the second embodiment;

FIG. 15A and FIG. 15B are schematic cross-sectional views illustrating the electronic device according to the second embodiment;

FIG. 16A and FIG. 16B are schematic views illustrating another electronic device according to the second embodiment; and

FIG. 17 is a schematic view illustrating another electronic device according to the second embodiment.

### DETAILED DESCRIPTION

According to one embodiment, a sensor includes a first film, a first sensor portion, a first terminal, a second terminal, a third terminal, a fourth terminal. The first film includes a first electrode layer, a second electrode layer, and a piezoelectric layer provided between the first electrode layer and the second electrode layer. The first film is deformable. The first sensor portion is fixed to a portion of the first film. A first direction from the portion of the first film toward the first sensor portion is aligned with a direction from the second electrode layer toward the first electrode layer. The first sensor portion includes a first sensor conductive layer, a second sensor conductive layer, a first magnetic layer provided between the first sensor conductive layer and the second sensor conductive layer, a second magnetic layer provided between the first magnetic layer and the second sensor conductive layer, and a first intermediate layer provided between the first magnetic layer and the second magnetic layer. The first terminal is electrically connected to the first electrode layer. The second terminal is electrically connected to the second electrode layer. The third terminal is electrically connected to the first sensor conductive layer. The fourth terminal is electrically connected to the second sensor conductive layer.

According to one embodiment, a sensor includes a first film and a first sensor portion. The first film includes a first electrode layer, a second electrode layer, and a piezoelectric layer provided between the first electrode layer and the second electrode layer. The first film is deformable. The first sensor portion is fixed to a portion of the first film. A first direction from the portion of the first film toward the first sensor portion is aligned with a direction from the second electrode layer toward the first electrode layer. The first sensor portion includes a first sensor conductive layer, a second sensor conductive layer, a first magnetic layer provided between the first sensor conductive layer and the second sensor conductive layer, a second magnetic layer provided between the first magnetic layer and the second sensor conductive layer, and a first intermediate layer provided between the first magnetic layer and the second magnetic layer. A first terminal is electrically connected to the first electrode layer and the second sensor conductive layer. A second terminal is electrically connected to the second electrode layer. A third terminal is electrically connected to the first sensor conductive layer.

According to one embodiment, an electronic device includes a sensor and a housing. The sensor includes a first film, a first sensor portion, a first terminal, a second terminal, a third terminal, a fourth terminal. The first film includes a first electrode layer, a second electrode layer, and a piezoelectric layer provided between the first electrode layer and the second electrode layer. The first film is deformable. The first sensor portion is fixed to a portion of the first film. A first direction from the portion of the first film toward the first sensor portion is aligned with a direction from the second electrode layer toward the first electrode layer. The first sensor portion includes a first sensor conductive layer, a second sensor conductive layer, a first magnetic layer provided between the first sensor conductive layer and the second sensor conductive layer, a second magnetic layer provided between the first magnetic layer and the second sensor conductive layer, and a first intermediate layer provided between the first magnetic layer and the second magnetic layer. The first terminal is electrically connected to the first electrode layer. The second terminal is electrically connected to the second electrode layer. The third terminal is electrically connected to the first sensor conductive layer. The fourth terminal is electrically connected to the second sensor conductive layer.

Embodiments will now be described with reference to the drawings.

The drawings are schematic or conceptual; and the relationships between the thicknesses and widths of portions, the proportions of sizes between portions, etc., are not necessarily the same as the actual values thereof. There are also cases where the dimensions and/or the proportions are illustrated differently between the drawings, even in the case where the same portion is illustrated.

In this specification and each drawing, components similar to ones described in reference to an antecedent drawing are marked with the same reference numerals; and a detailed description is omitted as appropriate.

### First Embodiment

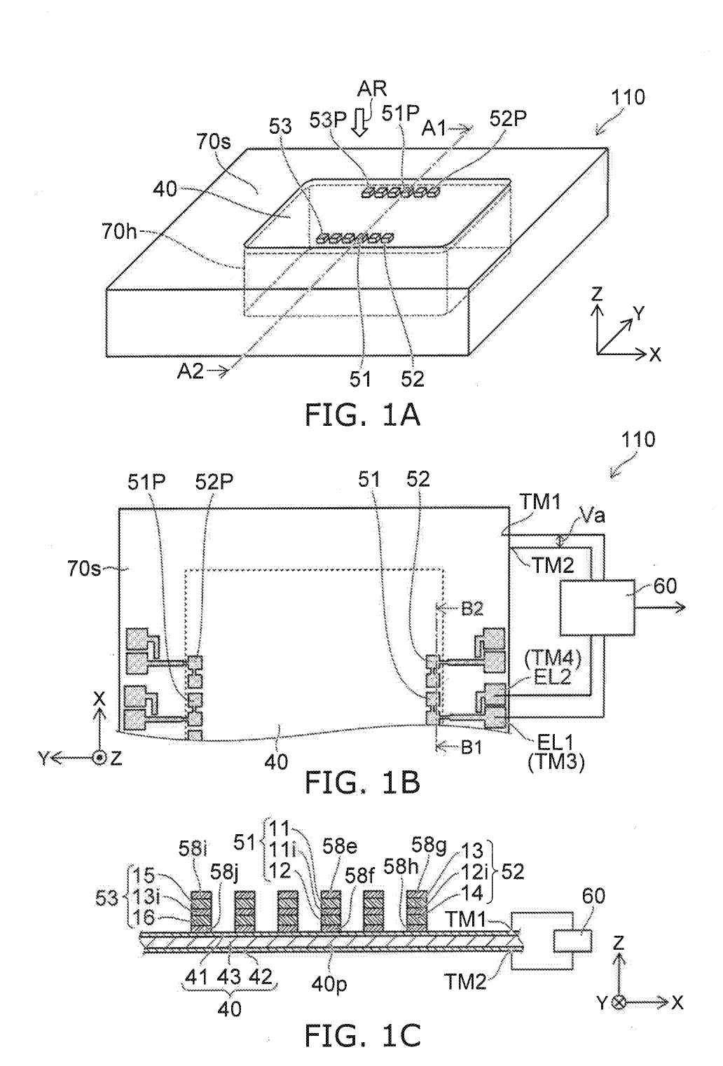

FIG. 1A to FIG. 1C are schematic views illustrating a sensor according to a first embodiment.

FIG. 1A is a perspective view. FIG. 1B is a plan view showing a portion of the sensor when viewed along arrow AR of FIG. 1A. FIG. 1C is a line B1-B2 cross-sectional view of FIG. 1B.

As shown in FIG. 1A to FIG. 1C, the sensor 110 according to the embodiment includes a first film 40, a first sensor portion 51, a first terminal TM1, a second terminal TM2, a third terminal TM3, and a fourth terminal TM4. The sensor 110 is, for example, a pressure sensor.

The first film 40 is deformable. For example, the first film 40 is supported by a supporter 70s. For example, a layer that is used to form the first film 40 is formed on a substrate used to form the supporter 70s. A recess 70h (a hole) is formed in a portion of the substrate. The thick portion (the portion where the recess 70h is not provided) of the substrate is used to form the supporter 70s. In the example, the first film 40 is provided on the supporter 70s and the recess 70h. The planar configuration of the region (a second region R2 described below with reference to FIG. 3) of the first film 40 provided on the recess 70h is, for example, substantially a quadrilateral (including a rectangle, etc.), a circle (including a flattened circle), etc. The deformable film recited above may have a free end. The supporter 70s includes, for example, silicon.

The first sensor portion 51 is provided at the first film 40. The first sensor portion 51 is fixed on a surface of a portion 40p of the first film 40. The front and back (the top and bottom) of the surface are arbitrary.

As shown in FIG. 1C, the first sensor portion 51 includes a first sensor conductive layer 58e, a first magnetic layer 11, a second magnetic layer 12, a first intermediate layer 11i, and a second sensor conductive layer 58f. The second sensor conductive layer 58f is provided between the first sensor conductive layer 58e and the first film 40. The first magnetic layer 11 is provided between the first sensor conductive layer 58e and the second sensor conductive layer 58f. The second magnetic layer 12 is provided between the first magnetic layer 11 and the second sensor conductive layer 58f. The first intermediate layer 11i is provided between the first magnetic layer 11 and the second magnetic layer 12.

A direction (a first direction) that connects the first film 40 and the first sensor portion 51 is taken as a Z-axis direction. For example, the first sensor portion 51 is provided at the portion 40p of the first film 40. In such a case, the direction of the shortest line connecting the first sensor portion 51 and the portion 40p of the first film 40 corresponds to the first direction.

One axis perpendicular to the Z-axis direction is taken as an X-axis direction. A direction perpendicular to the Z-axis direction and the X-axis direction is taken as a Y-axis direction. In the example, the direction from the second magnetic layer 12 toward the first magnetic layer 11 corresponds to the Z-axis direction.

Multiple sensor portions (e.g., a second sensor portion 52, a third sensor portion 53, a sensor portion 51P, a sensor portion 52P, a sensor portion 53P, etc.) are provided in the example. In the example, at least a portion of the second sensor portion 52 overlaps at least a portion of the first sensor portion 51 along the X-axis direction. The first sensor portion 51 is provided between the second sensor portion 52 and the third sensor portion 53. At least a portion of the sensor portion 51P overlaps at least a portion of the first sensor portion 51 along the Y-axis direction. At least a portion of the sensor portion 52P overlaps at least a portion of the second sensor portion 52 along the Y-axis direction. At least a portion of the sensor portion 53P overlaps at least a portion of the third sensor portion 53 along the Y-axis direction.

The second sensor portion 52 includes a third sensor conductive layer 58g, a third magnetic layer 13, a fourth magnetic layer 14, a second intermediate layer 12i, and a fourth sensor conductive layer 58h. The fourth sensor conductive layer 58h is provided between the third sensor conductive layer 58g and the first film 40. The third magnetic layer 13 is provided between the third sensor conductive layer 58g and the fourth sensor conductive layer 58h. The fourth magnetic layer 14 is provided between the third magnetic layer 13 and the fourth sensor conductive layer 58h. The second intermediate layer 12i is provided between the third magnetic layer 13 and the fourth magnetic layer 14.

The third sensor portion 53 includes a fifth sensor conductive layer 58i, a fifth magnetic layer 15, a sixth magnetic layer 16, a third intermediate layer 13i, and a sixth sensor conductive layer 58j. The sixth sensor conductive layer 58j is provided between the fifth sensor conductive layer 58i and the first film 40. The fifth magnetic layer 15 is provided between the fifth sensor conductive layer 58i and the sixth sensor conductive layer 58j. The sixth magnetic layer 16 is provided between the fifth magnetic layer 15 and the sixth sensor conductive layer 58j. The third intermediate layer 13i is provided between the fifth magnetic layer 15 and the sixth magnetic layer 16.

The configurations of the sensor portions 51P to 53P are similar to those of the first to third sensor portions 51 to 53.

The first sensor conductive layer 58e of the first sensor portion 51 is electrically connected to a first sensor electrode EL1 (the third terminal TM3). The second sensor conductive layer 58f of the first sensor portion 51 is electrically connected to a second sensor electrode EL2 (the fourth terminal TM4). For example, the first sensor conductive layer 58e, the second sensor conductive layer 58f, the first sensor electrode EL1, and the second sensor electrode EL2 each include at least one selected from the group consisting of Al (aluminum), Cu (copper), Ag (silver), and Au (gold).

The electrical resistance between the first magnetic layer 11 and the second magnetic layer 12 (the electrical resistance of the first sensor portion 51) changes according to the deformation (a strain ε) of the first film 40. For example, the pressure that is applied to the first film 40 can be sensed by sensing the change of the electrical resistance between the first sensor electrode EL1 and the second sensor electrode EL2. The pressure is, for example, a sound wave, etc.

For example, the orientation of the magnetization of at least one of the first magnetic layer 11 or the second magnetic layer 12 changes according to the deformation of the first film 40. The change of the orientation of the magnetization is the change of the electrical resistance recited above. For example, the angle between the magnetization of the first magnetic layer 11 and the magnetization of the second magnetic layer 12 changes according to the deformation of the first film 40. The electrical resistance changes due to the change of this angle.

In the embodiment, the state of being electrically connected includes not only the state in which multiple conductors are in direct contact, but also the case where the multiple conductors are connected via another conductor. The state of being electrically connected includes the case where multiple conductors are connected via an element having a function such as switching, amplification, etc.

For example, at least one of a switch element or an amplifier element may be inserted into at least one of a current path between the first sensor electrode EL1 and the first magnetic layer 11 or a current path between the second sensor electrode EL2 and the second magnetic layer 12.

For example, the first magnetic layer 11 is a free magnetic layer; and the second magnetic layer 12 is a magnetization reference layer. For example, the first magnetic layer 11 may be a magnetization reference layer; and the second magnetic layer 12 may be a free magnetic layer. Both the first magnetic layer 11 and the second magnetic layer 12 may be free magnetic layers. The description relating to the first sensor portion 51 recited above is applicable also to the other sensor portions (the second sensor portion 52, the third sensor portion 53, the sensor portion 51P, the sensor portion 52P, the sensor portion 53P, etc.).

The first film 40 includes a first electrode layer 41, a second electrode layer 42, and a piezoelectric layer 43. These layers are stacked in the first direction (the Z-axis direction). The direction from the second electrode layer 42 toward the first electrode layer 41 is aligned with the first direction. The first electrode layer 41 is provided between the first sensor portion 51 and the second electrode layer 42. The piezoelectric layer 43 is provided between the first electrode layer 41 and the second electrode layer 42. A portion of the piezoelectric layer 43 overlaps the first sensor portion 51 in the first direction (the Z-axis direction).

The piezoelectric layer 43 includes, for example, lead zirconate titanate (Pb(ZrₓTi₁₋ₓ)O₃ (PZT)), aluminum nitride (Al—N), zinc oxide (Zn—O), etc. The piezoelectric layer 43 may include a polymer. The piezoelectric layer 43 includes, for example, barium titanate (BaTiO₃), lead titanate (PbTiO₃), potassium niobate (KNbO₃), lithium niobate (LiNbO₃), lithium tantalate (LiTaO₃), sodium tungstate (NaWO₃), sodium titanate (NaTiO₃), bismuth titanate (BiTiO₃ or Bi₄Ti₃O₁₂), sodium potassium niobate ((K, Na)NbO₃), sodium niobate (NaBbO₃), bismuth ferrite (BiFeO₃), bismuth sodium titanate (Na_{0.5}Bi_{0.5}TiO₃), Ba₂NaNb₅O₅, Pb₂KNbO₁₅, and lithium tetraborate (Li₂B₄O₇). The piezoelectric layer 43 includes, for example, quartz (crystal: Si—O), gallium phosphate (GaPO₄), gallium arsenide (Ga—As), langasite (La₃Ga₅SiO₁₄), etc.

The first electrode layer 41 is electrically connected to the first terminal TM1. The second electrode layer 42 is electrically connected to the second terminal TM2. For example, the first electrode layer 41 and the second electrode layer 42 include molybdenum (Mo). For example, the first electrode layer 41 and the second electrode layer 42 include platinum (Pt). For example, the first electrode layer 41 and the second electrode layer 42 include at least one selected from the group consisting of Al, Cu, Ag, and Au. For example, the first terminal TM1 and the second terminal TM2 include at least one selected from the group consisting of Al, Cu, Ag, and Au.

As shown in FIG. 1B and FIG. 1C, the sensor 110 may further include a controller 60 (a control circuit). The controller 60 is electrically connected to the first sensor electrode EL1 and the second sensor electrode EL2.

The controller 60 is electrically connected to the first terminal TM1 and the second terminal TM2. The controller 60 controls a potential difference Va between the first terminal TM1 and the second terminal TM2.

By the control of the potential difference Va, a voltage is applied between the first electrode layer 41 and the second electrode layer 42; and the voltage is applied to the piezoelectric layer 43. According to the voltage, the tensile stress of the piezoelectric layer 43 can be changed by the piezoelectric effect. By the change of the tensile stress, for example, the resonant frequency of the first film 40 can be adjusted. By the change of the tensile stress, for example, the ease (the sensitivity) of the generation of the strain e when a pressure P is applied to the first film 40 can be adjusted. Thereby, the resonant frequency and/or sensitivity can be adjusted; and the sensing precision of the sensor can be increased. For example, the potential difference Va is changed to match the sensing object. For example, the band of the frequency of the sensing object can be enlarged by changing the resonant frequency.

An example of characteristics of the sensor will now be described.

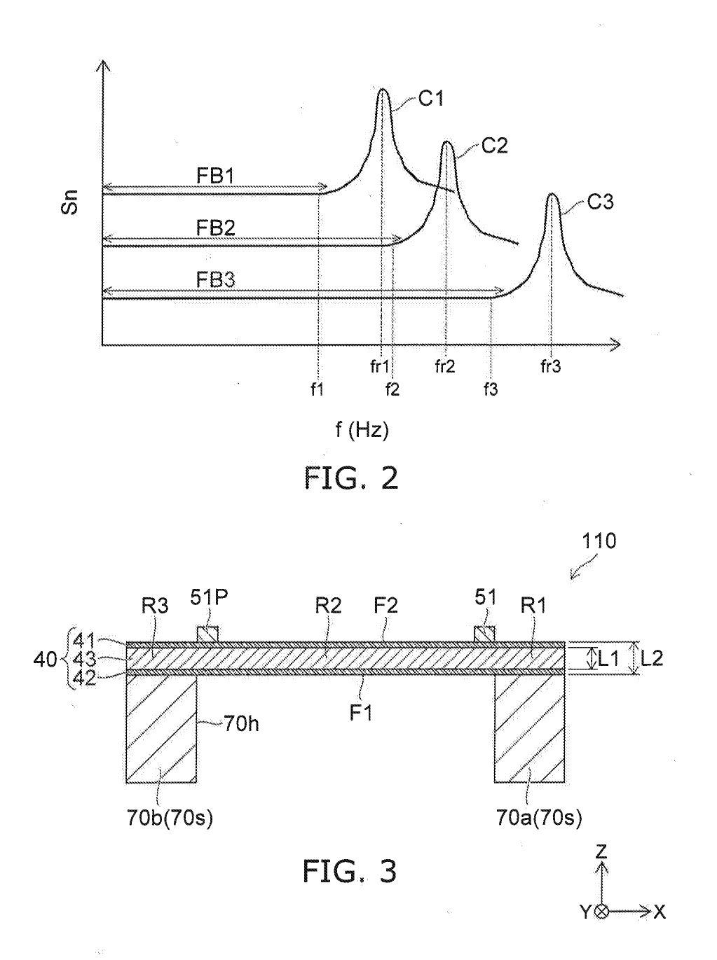

FIG. 2 is a schematic view illustrating characteristics of the sensor according to the first embodiment.

The horizontal axis of FIG. 2 is a frequency f (Hz); and the vertical axis of FIG. 2 is a sensitivity Sn of the sensor. The sensitivity Sn corresponds to the magnitude (the strain slope dε/dP) of the strain ε generated in the first film 40 by the pressure P applied to the first film 40.

FIG. 2 shows a characteristic C1 in a first state ST1, a characteristic C2 in a second state ST2, and a characteristic C3 in a third state ST3. The first state ST1 is the state in which the potential difference Va between the first terminal TM1 and the second terminal TM2 is a first potential difference V1 (a first value). The second state ST2 is the state in which the potential difference Va is a second potential difference V2 (a second value). The third state ST3 is the state in which the potential difference Va is a third potential difference V3 (a third value). The first potential difference V1, the second potential difference V2, and the third potential difference V3 are different from each other. For example, the absolute value of the second potential difference V2 is greater than the absolute value of the first potential difference V1. For example, the absolute value of the third potential difference V3 is greater than the absolute value of the second potential difference V2.

The resonant frequency of the first film 40 in the first state ST1 is a first resonant frequency fr1. The resonant frequency of the first film 40 in the second state ST2 is a second resonant frequency fr2. The resonant frequency of the first film 40 in the third state ST3 is a third resonant frequency fr3. The second resonant frequency fr2 is higher than the first resonant frequency fr1. The third resonant frequency fr3 is higher than the second resonant frequency fr2.

The sensitivity Sn in the second state ST2 is lower than the sensitivity Sn in the first state ST1. The sensitivity Sn in the third state ST3 is lower than the sensitivity Sn in the second state ST2.

Thus, according to the embodiment, the frequency characteristic of the sensitivity can be changed by the voltage applied to the piezoelectric layer 43. Thereby, the sensing precision can be increased.

FIG. 3 is a schematic cross-sectional view illustrating the sensor according to the first embodiment.

The cross-sectional view is a line A1-A2 cross-sectional view shown in FIG. 1A. As shown in FIG. 3, the supporter 70s supports the first film 40. The supporter 70s includes a first portion 70a and a second portion 70b. A second direction from the first portion 70a toward the second portion 70b crosses the first direction (the Z-axis direction). The second direction is a direction along the X-axis direction.

The piezoelectric layer 43 includes a first region R1, the second region R2, and a third region R3. The second region R2 is continuous with the first region R1 and the third region R3. The first region R1 overlaps the first portion 70a of the supporter 70s in the Z-axis direction. A direction from the first portion 70a of the supporter 70s toward the first region R1 is along the first direction (the Z-axis direction). The second region R2 does not overlap the supporter 70s in the Z-axis direction. A direction from the supporter 70s toward the second region R2 crosses the first direction (the Z-axis direction). The third region R3 overlaps the second portion 70b of the supporter 70s in the Z-axis direction. A direction from the second portion 70b of the supporter 70s toward the third region R3 is along the first direction (the Z-axis direction). For example, the first film 40 (the piezoelectric layer 43) is provided over the entire supporter 70s and the entire recess 70h.

The sensor portions (the first sensor portion 51, etc.) overlap the second region R2 in the Z-axis direction. The second region R2 includes the portion 40p of the first film 40 shown in FIG. 1C. For example, the first sensor portion 51 does not overlap the supporter 70s in the Z-axis direction.

The first film 40 has a first surface F1 and a second surface F2. The direction from the first surface F1 toward the second surface F2 is aligned with the Z-axis direction. The first surface F1 and the second surface F2 each contact at least one of a gas or a liquid. For example, due to at least one of a gas or a liquid that is vibrated, the pressure is applied to the first film 40; and the strain E is generated in the first film 40.

A length L1 along the Z-axis direction of the piezoelectric layer 43 is, for example, not less than 0.5 times and not more than 0.995 times a length L2 along the Z-axis direction of the first film 40. In other words, the proportion occupied by the piezoelectric layer 43 inside the layers included in the first film 40 is larger than the proportion occupied by the other layers.

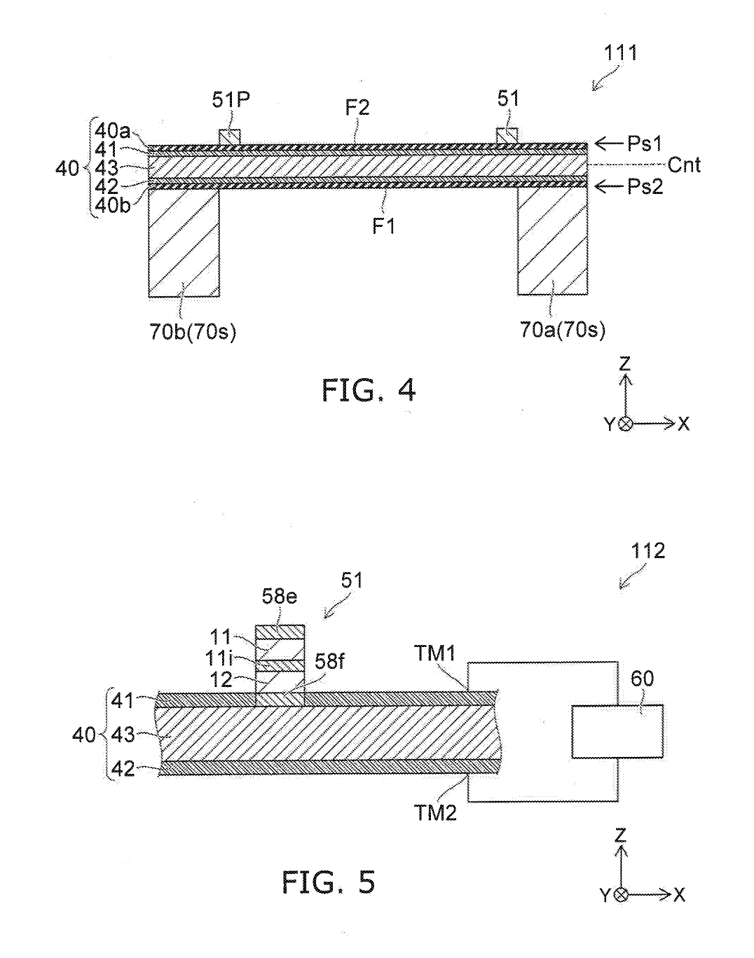

FIG. 4 is a schematic cross-sectional view illustrating another sensor according to the first embodiment.

The cross section shown in FIG. 4 corresponds to the line A1-A2 cross section of FIG. 1A.

In the sensor 111 shown in FIG. 4, the first film 40 further includes a first layer 40a and a second layer 40b. Otherwise, the configuration of the sensor 111 is similar to that of the sensor 110 described above. For example, the first layer 40a and the second layer 40b each include aluminum oxide. For example, the first layer 40a and the second layer 40b each include at least one of aluminum nitride, silicon oxide, or silicon nitride.

The first layer 40a is provided at one of a first position Ps1 or a second position Ps2. The second layer 40b is provided at the other of the first position Ps1 or the second position Ps2. In the example, the first layer 40a is provided at the first position Ps1; and the second layer 40b is provided at the second position Ps2.

The first electrode layer 41 is positioned between the first position Ps1 and the second electrode layer 42 in the Z-axis direction. The second electrode layer 42 is positioned between the second position Ps2 and the first electrode layer 41 in the Z-axis direction. A center Cnt of the first film 40 in the Z-axis direction is between the first position Ps1 and the second position Ps2 in the Z-axis direction.

FIG. 5 is a schematic cross-sectional view illustrating another sensor according to the first embodiment.

The cross section shown in FIG. 5 corresponds to the cross section shown in FIG. 1C. In the sensor 112 shown in FIG. 5, the second sensor conductive layer 58f is electrically connected to the first electrode layer 41. For example, the second sensor conductive layer 58f is continuous with the first electrode layer 41. The second sensor conductive layer 58f and the first electrode layer 41 may be formed as one conductive layer.

The first terminal TM1 is electrically connected to the first electrode layer 41. In other words, in the example, the first terminal TM1 is electrically connected to the first electrode layer 41 and the second sensor conductive layer 58f. Otherwise, the sensor 112 is similar to the sensor 110 described above.

An example of a system including the sensor according to the first embodiment will now be described.

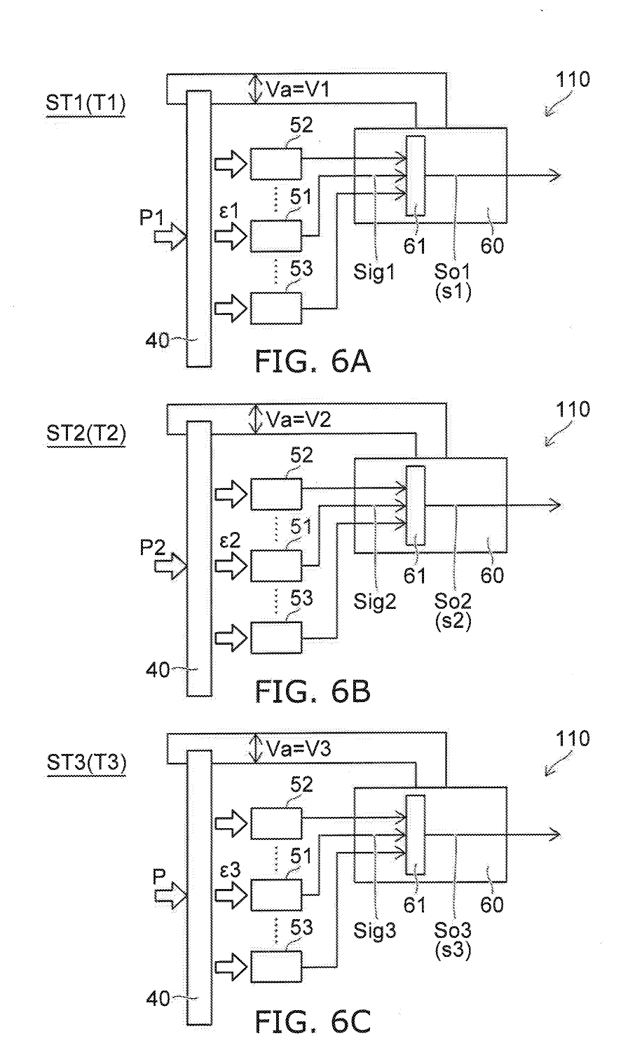

FIG. 6A to FIG. 6C are block diagrams illustrating the sensor according to the first embodiment.

FIG. 6A illustrates the first state ST1. In the first state ST1, the controller 60 executes a first control of setting the potential difference Va between the first terminal TM1 and the second terminal TM2 to the first potential difference V1. The controller 60 executes the first control in a first interval T1.

A strain ε1 is generated when a pressure P1 (e.g., a sound wave) to be sensed is applied to the first film 40. A change of the electrical resistance occurs in the sensor portions (the first to third sensor portions 51 to 53, etc.) due to the strain ε1. For example, two or more of these sensor portions may be connected in series. The change of the electrical resistance is sensed by the controller 60. In the first state ST1, for example, the change of the electrical resistance is sensed according to the characteristic C1 shown in FIG. 2.

The controller 60 may include a filter circuit 61. In the example, the case is considered where the signal of a frequency band that is lower than the resonant frequency of the first film 40 is used to sense the pressure. In other words, a relatively flat band of the frequency characteristic of the sensitivity is utilized.

In the first state ST1, the filter circuit 61 acquires a first signal Sig1 relating to the change of the electrical resistance of the sensor portions (the first sensor portion 51, etc.) and outputs a first output signal So1. In the first state ST1, for example, the filter circuit 61 blocks the component of the frequency equal to or more than the first resonant frequency fr1 of the first signal Sig1 and transmits the component of the frequency that is lower than the first resonant frequency fr1 of the first signal Sig1. In other words, the first output signal So1 includes a component (a first component s1) of a first frequency f1 that is lower than the first resonant frequency fr1. The band of the frequency sensed by the sensor in the first state ST1 (the first interval T1) is, for example, a first band FB1 shown in FIG. 2.

FIG. 6B illustrates the second state ST2. In the second state, the controller 60 executes a second control of setting the potential difference Va to the second potential difference V2. The controller 60 executes the second control in a second interval T2 that is different from the first interval T1.

A strain ε2 is generated when a pressure P2 (e.g., a sound wave) to be sensed is applied to the first film 40. A change of the electrical resistance occurs in the sensor portions (the first sensor portion 51, etc.) due to the strain ε2. The change of the electrical resistance is sensed by the controller 60. In the second state ST2, for example, the change of the electrical resistance is sensed according to the characteristic C2 shown in FIG. 2.

In the second state ST2, the filter circuit 61 acquires a second signal Sig2 relating to the change of the electrical resistance of the sensor portions (the first sensor portion 51, etc.) and outputs a second output signal So2. In the second state ST2, for example, the filter circuit 61 blocks the component of the frequency equal to or more than the second resonant frequency fr2 of the second signal Sig2 and transmits the component of the frequency that is lower than the second resonant frequency fr2 of the second signal Sig2. In other words, the second output signal So2 includes a component (a second component s2) of a second frequency f2 that is lower than the second resonant frequency fr2. As shown in FIG. 2, for example, the second frequency f2 is the first resonant frequency fr1 or more. The band of the frequency sensed by the sensor in the second state ST2 (the second interval T2) is, for example, a second band FB2 shown in FIG. 2.

FIG. 6C illustrates the third state ST3. In the third state ST3, the controller 60 executes a third control of setting the potential difference Va to the third potential difference V3. The controller 60 executes the third control in a third interval T3 that is different from the first interval T1 and the second interval T2.

A strain s3 is generated when a pressure P3 (e.g., a sound wave) to be sensed is applied to the first film 40. A change of the electrical resistance occurs in the sensor portions (the first sensor portion 51, etc.) due to the strain ε3. The change of the electrical resistance is sensed by the controller 60. In the third state ST3, for example, the change of the electrical resistance is sensed according to the characteristic C3 shown in FIG. 2.

In the third state ST3, the filter circuit 61 acquires a third signal Sig3 relating to the change of the electrical resistance of the sensor portions (the first sensor portion 51, etc.) and outputs a third output signal So3. In the third state ST3, for example, the filter circuit 61 blocks the component of the frequency equal to or more than the third resonant frequency fr3 of the third signal Sig3 and transmits the component of the frequency that is lower than the third resonant frequency fr3 of the third signal Sig3. In other words, the third output signal So3 includes a component (a third component s3) of a third frequency f3 that is lower than the third resonant frequency fr3. As shown in FIG. 2, for example, the third frequency f3 is the second resonant frequency fr2 or more. The band of the frequency sensed by the sensor in the third state ST3 (the third interval T3) is, for example, a third band FB3 shown in FIG. 2.

As described above, the resonant frequency of the first film 40 is changed for each interval by changing the voltage applied to the piezoelectric layer 43. In the case where the signal of the frequency band that is lower than the resonant frequency is used to sense the pressure, the frequency band sensed by the sensor can be widened by setting the resonant frequency to be high. On the other hand, as described in reference to FIG. 2, for example, the sensitivity in the second state ST2 and the sensitivity in the third state ST3 are lower than the sensitivity in the first state ST1.

In the embodiment, by changing the resonant frequency for each interval, the frequency band that is lower than the first resonant frequency fr1 is sensed in the highly-sensitive first state ST1. In the second state ST2, for example, the frequency band that is not less than the first resonant frequency fr1 but lower than the second resonant frequency fr2 is sensed. In the third state ST3, for example, the sensing band that is not less than the second resonant frequency fr2 but lower than the third resonant frequency fr3 is sensed. Thereby, a highly-sensitive measurement is possible in a wide bandwidth. For example, the first resonant frequency fr1 is not less than 5 kHz and not more than 50 kHz. For example, the second resonant frequency fr2 is not less than 50 kHz and not more than 100 kHz. For example, the third resonant frequency fr3 is not less than 100 kHz and not more than 500 kHz. For example, the second resonant frequency fr2 is not less than 5 times the first resonant frequency fr1. For example, the controller 60 repeats the first to third controls.

The controller 60 may include an amplifier circuit. The amplifier circuit can perform weighting processing of the first signal Sig1, the second signal Sig2, and the third signal Sig3. For example, the weighting processing can be performed to even out the difference of the sensitivities Sn between the first state ST1, the second state ST2, and the third state ST3. For example, at least one of the first output signal So1 based on the first signal Sig1 or the second output signal So2 based on the second signal Sig2 is based on the sensitivity Sn in the first state ST1 and the sensitivity Sn in the second state ST2. For example, in the case where the sensitivity Sn in the second state ST2 is 1/A times the sensitivity Sn in the first state ST1, the controller 60 can output the second output signal So2 by amplifying the second signal Sig2 A times. For example, in the case where the sensitivity Sn in the third state ST3 is 1/B times the sensitivity Sn in the first state. ST1, the controller 60 can output the third output signal So3 by amplifying the third signal Sig3 B times.

The sensitivity Sn in the first state ST1 corresponds to the sensitivity of the change of the electrical resistance of the sensor portion in the first state ST1 (the magnitude of the change of the electrical resistance of the sensor portion with respect to the change of the pressure P applied to the first film 40). Similarly, the sensitivity Sn in the second state ST2 corresponds to the sensitivity of the change of the electrical resistance of the sensor portion in the second state ST2; and the sensitivity Sn in the third state ST3 corresponds to the sensitivity of the change of the electrical resistance of the sensor portion in the third state ST3.

The controller 60 may output the first to third output signals So1 to So3 separately or may output the first to third output signals So1 to So3 as a sum.

In the embodiment, the signal that is used to sense the pressure is not limited to a band that is lower than the resonant frequency. A signal in a band including the resonant frequency may be used to sense the pressure.

Examples of sensor portions used in the embodiments will now be described. In the following description, the notation “material A/material B” indicates a state in which a layer of the material B is provided on a layer of the material A.

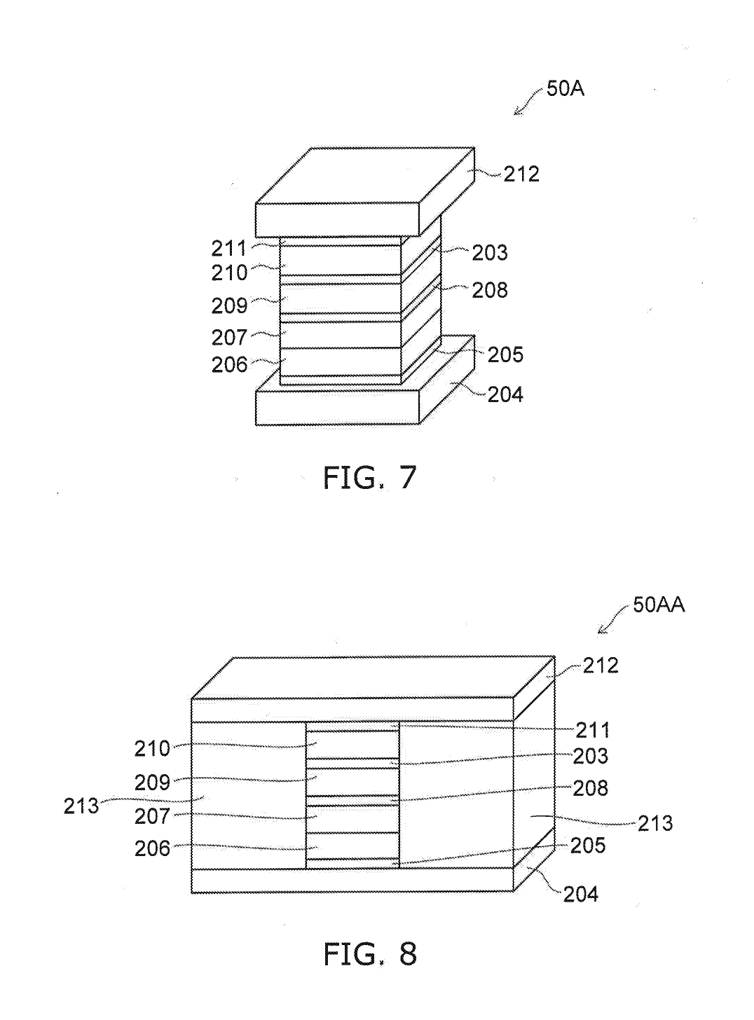

FIG. 7 is a schematic perspective view illustrating a portion of the sensor according to the embodiment.

In the sensor portion 50A as shown in FIG. 7, a lower electrode 204, a foundation layer 205, a pinning layer 206, a second magnetization reference layer 207, a magnetic coupling layer 208, a first magnetization reference layer 209, an intermediate layer 203, a free magnetic layer 210, a capping layer 211, and an upper electrode 212 are arranged in this order. The sensor portion 50A is, for example, a bottom spin-valve type. The magnetization reference layer is, for example, a fixed magnetic layer.

The foundation layer 205 includes, for example, a stacked film of tantalum and ruthenium (Ta/Ru). The thickness (the length in the Z-axis direction) of the Ta layer is, for example, 3 nanometers (nm). The thickness of the Ru layer is, for example, 2 nm. The pinning layer 206 includes, for example, an IrMn-layer having a thickness of 7 nm. The second magnetization reference layer 207 includes, for example, a Co₇₅Fe₂₅ layer having a thickness of 2.5 nm. The magnetic coupling layer 208 includes, for example, a Ru layer having a thickness of 0.9 nm. The first magnetization reference layer 209 includes, for example, a Co₄₀Fe₄₀B₂₀ layer having a thickness of 3 nm. The intermediate layer 203 includes, for example, a MgO layer having a thickness of 1.6 nm. The free magnetic layer 210 includes, for example, Co₄₀Fe₄₀B₂₀ having a thickness of 4 nm. The capping layer 211 includes, for example, Ta/Ru. The thickness of the Ta layer is, for example, 1 nm. The thickness of the Ru layer is, for example, 5 nm.

The lower electrode 204 and the upper electrode 212 include, for example, at least one selected from the group consisting of aluminum (Al), an aluminum copper alloy (Al—Cu), copper (Cu), silver (Ag), and gold (Au). By using such a material having a relatively small electrical resistance as the lower electrode 204 and the upper electrode 212, the current can be caused to flow efficiently in the sensor portion 50A. The lower electrode 204 and the upper electrode 212 include nonmagnetic materials.

The lower electrode 204 and the upper electrode 212 may include, for example, a foundation layer (not illustrated) for the lower electrode 204 and the upper electrode 212, a capping layer (not illustrated) for the lower electrode 204 and the upper electrode 212, and a layer of at least one selected from the group consisting of Al, Al—Cu, Cu, Ag, and Au provided between the foundation layer and the capping layer. For example, the lower electrode 204 and the upper electrode 212 include tantalum (Ta)/copper (Cu)/tantalum (Ta), etc. For example, by using Ta as the foundation layer of the lower electrode 204 and the upper electrode 212, the adhesion between the substrate (e.g., the film) and the lower electrode 204 and between the substrate (e.g., the film) and the upper electrode 212 improves. Titanium (Ti), titanium nitride (TiN), etc., may be used as the foundation layer for the lower electrode 204 and the upper electrode 212.

By using Ta as the capping layer of the lower electrode 204 and the upper electrode 212, the oxidization of the copper (Cu), etc., under the capping layer is suppressed. Titanium (Ti), titanium nitride (TiN), etc., may be used as the capping layer for the lower electrode 204 and the upper electrode 212.

The foundation layer 205 includes, for example, a stacked structure including a buffer layer (not illustrated) and a seed layer (not illustrated). For example, the buffer layer relaxes the roughness of the surfaces of the lower electrode 204, the film, etc., and improves the crystallinity of the layers stacked on the buffer layer. For example, at least one selected from the group consisting of tantalum (Ta), titanium (Ti), vanadium (V), tungsten (W), zirconium (Zr), hafnium (Hf), and chrome (Cr) is used as the buffer layer. An alloy that includes at least one material selected from these materials may be used as the buffer layer.

It is favorable for the thickness of the buffer layer of the foundation layer 205 to be not less than 1 nm and not more than 10 nm. It is more favorable for the thickness of the buffer layer to be not less than 1 nm and not more than 5 nm. In the case where the thickness of the buffer layer is too thin, the buffering effect is lost. In the case where the thickness of the buffer layer is too thick, the thickness of the sensor portion 50A becomes excessively thick. The seed layer is formed on the buffer layer; and, for example, the seed layer has a buffering effect. In such a case, the buffer layer may be omitted. The buffer layer includes, for example, a Ta layer having a thickness of 3 nm.

The seed layer of the foundation layer 205 controls the crystal orientation of the layers stacked on the seed layer. The seed layer controls the crystal grain size of the layers stacked on the seed layer. As the seed layer, a metal having a fcc structure (a face-centered cubic structure), a hcp structure (a hexagonal close-packed structure), a bcc structure (a body-centered cubic structure), or the like is used.

For example, the crystal orientation of the spin-valve film on the seed layer can be set to the fcc (111) orientation by using, as the seed layer of the foundation layer 205, ruthenium (Ru) having a hcp structure, NiFe having a fcc structure, or Cu having a fcc structure. The seed layer includes, for example, a Cu layer having a thickness of 2 nm or a Ru layer having a thickness of 2 nm. To increase the crystal orientation of the layers formed on the seed layer, it is favorable for the thickness of the seed layer to be not less than 1 nm and not more than 5 nm. It is more favorable for the thickness of the seed layer to be not less than 1 nm and not more than 3 nm. Thereby, the function as a seed layer that improves the crystal orientation is realized sufficiently.

On the other hand, for example, the seed layer may be omitted in the case where it is unnecessary for the layers formed on the seed layer to have a crystal orientation (e.g., in the case where an amorphous free magnetic layer is formed, etc.). For example, a Cu layer having a thickness of 2 nm is used as the seed layer.

For example, the pinning layer 206 provides unidirectional anisotropy to the second magnetization reference layer 207 (the ferromagnetic layer) formed on the pinning layer 206 and fixes the magnetization of the second magnetization reference layer 207. The pinning layer 206 includes, for example, an antiferromagnetic layer. The pinning layer 206 includes, for example, at least one selected from the group consisting of Ir—Mn, Pt—Mn, Pd—Pt—Mn, Ru—Mn, Rh—Mn, Ru—Rh—Mn, Fe—Mn, Ni—Mn, Cr—Mn—Pt, and Ni—O. An alloy may be used in which an added element is further added to at least one selected from the group consisting of Ir—Mn, Pt—Mn, Pd—Pt—Mn, Ru—Mn, Rh—Mn, Ru—Rh—Mn, Fe—Mn, Ni—Mn, Cr—Mn—Pt, and Ni—O. The thickness of the pinning layer 206 is set appropriately. Thereby, for example, unidirectional anisotropy of sufficient strength is provided.

For example, heat treatment is performed while applying a magnetic field. Thereby, for example, the magnetization of the ferromagnetic layer contacting the pinning layer 206 is fixed. The magnetization of the ferromagnetic layer contacting the pinning layer 206 is fixed in the direction of the magnetic field applied in the heat treatment. For example, the heat treatment temperature (the annealing temperature) is not less than the magnetization pinning temperature of the antiferromagnetic material included in the pinning layer 206. In the case where an antiferromagnetic layer including Mn is used, there are cases where the MR ratio decreases due to the Mn diffusing into layers other than the pinning layer 206. It is desirable for the heat treatment temperature to be set to be not more than the temperature at which the diffusion of Mn occurs. The heat treatment temperature is, for example, not less than 200° C. and not more than 500° C. Favorably, the heat treatment temperature is, for example, not less than 250° C. and not more than 400° C.

In the case where PtMn or PdPtMn is used as the pinning layer 206, it is favorable for the thickness of the pinning layer 206 to be not less than 8 nm and not more than 20 nm. It is more favorable for the thickness of the pinning layer 206 to be not less than 10 nm and not more than 15 nm. In the case where IrMn is used as the pinning layer 206, unidirectional anisotropy can be provided using a thickness that is thinner than the case where PtMn is used as the pinning layer 206. In such a case, it is favorable for the thickness of the pinning layer 206 to be not less than 4 nm and not more than 18 nm. It is more favorable for the thickness of the pinning layer 206 to be not less than 5 nm and not more than 15 nm. The pinning layer 206 includes, for example, an Ir₂₂Mn₇₈ layer having a thickness of 7 nm.

A hard magnetic layer may be used as the pinning layer 206. For example, Co—Pt, Fe—Pt, Co—Pd, Fe—Pd, etc., may be used as the hard magnetic layer. For example, the magnetic anisotropy and the coercivity are relatively high for these materials. These materials are hard magnetic materials. An alloy in which an added element is further added to Co—Pt, Fe—Pt, Co—Pd, or Fe—Pd may be used as the pinning layer 206. For example, CoPt (the proportion of Co being not less than 50 at. % and not more than 85 at. %), (CoₓPt₁₀₀₋ₓ)_{100-y}Cr_{y} (x being not less than 50 at. % and not more than 85 at. %, and y being not less than 0 at. % and not more than 40 at. %), FePt (the proportion of Pt being not less than 40 at. % and not more than 60 at. %), etc., may be used.

The second magnetization reference layer 207 includes, for example, a CoₓFe₁₀₀₋ₓ alloy (x being not less than 0 at. % and not more than 100 at. %) or a NiₓFe₁₀₀₋ₓ alloy (x being not less than 0 at. % and not more than 100 at. %). These materials may include a material to which a nonmagnetic element is added. For example, at least one selected from the group consisting of Co, Fe, and Ni is used as the second magnetization reference layer 207. An alloy that includes at least one material selected from these materials may be used as the second magnetization reference layer 207. Also, a (CoₓFe₁₀₀₋ₓ)_{100-y}B_{y} alloy (x being not less than 0 at. % and not more than 100 at. %, and y being not less than 0 at. % and not more than 30 at. %) may be used as the second magnetization reference layer 207. By using an amorphous alloy of (CoₓFe₁₀₀₋ₓ)_{100-y}B_{y} as the second magnetization reference layer 207, the fluctuation of the characteristics of the sensor portion 50A can be suppressed even in the case where the sizes of the sensor portions are small.

For example, it is favorable for the thickness of the second magnetization reference layer 207 to be not less than 1.5 nm and not more than 5 nm. Thereby, for example, the strength of the unidirectional anisotropic magnetic field due to the pinning layer 206 can be stronger. For example, the strength of the antiferromagnetic coupling magnetic field between the second magnetization reference layer 207 and the first magnetization reference layer 209 via the magnetic coupling layer formed on the second magnetization reference layer 207 can be stronger. For example, it is favorable for the magnetic thickness (the product of the saturation magnetization and the thickness) of the second magnetization reference layer 207 to be substantially equal to the magnetic thickness of the first magnetization reference layer 209.

The saturation magnetization of a thin film of Co₄₀Fe₄₀B₂₀ is about 1.9 T (teslas). For example, in the case where a Co₄₀Fe₄₀B₂₀ layer having a thickness of 3 nm is used as the first magnetization reference layer 209, the magnetic thickness of the first magnetization reference layer 209 is 1.9 T×3 nm, i.e., 5.7 Tnm. On the other hand, the saturation magnetization of Co₇₅Fe₂₅ is about 2.1 T. The thickness of the second magnetization reference layer 207 to obtain a magnetic thickness equal to that recited above is 5.7 Tnm/2.1 T, i.e., 2.7 nm. In such a case, it is favorable for a Co₇₅Fe₂₅ layer having a thickness of about 2.7 nm to be included in the second magnetization reference layer 207. For example, a CO₇₅Fe₂₅ layer having a thickness of 2.5 nm is used as the second magnetization reference layer 207.

In the sensor portion 50A, a synthetic pinned structure that is made of the second magnetization reference layer 207, the magnetic coupling layer 208, and the first magnetization reference layer 209 is used. A single pinned structure that is made of one magnetization reference layer may be used instead. In the case where the single pinned structure is used, for example, a Co₄₀Fe₄₀B₂₀ layer having a thickness of 3 nm is used as the magnetization reference layer. The same material as the material of the second magnetization reference layer 207 described above may be used as the ferromagnetic layer included in the magnetization reference layer having the single pinned structure.

The magnetic coupling layer 208 causes antiferromagnetic coupling to occur between the second magnetization reference layer 207 and the first magnetization reference layer 209. The magnetic coupling layer 208 has a synthetic pinned structure. For example, Ru is used as the material of the magnetic coupling layer 208. For example, it is favorable for the thickness of the magnetic coupling layer 208 to be not less than 0.8 nm and not more than 1 nm. A material other than Ru may be used as the magnetic coupling layer 208 if the material causes sufficient antiferromagnetic coupling to occur between the second magnetization reference layer 207 and the first magnetization reference layer 209. For example, the thickness of the magnetic coupling layer 208 is set to a thickness not less than 0.8 nm and not more than 1 nm corresponding to the second peak (2nd peak) of RKKY (Ruderman-Kittel-Kasuya-Yosida) coupling. Further, the thickness of the magnetic coupling layer 208 may be set to a thickness not less than 0.3 nm and not more than 0.6 nm corresponding to the first peak (1st peak) of RKKY coupling. For example, Ru having a thickness of 0.9 nm is used as the material of the magnetic coupling layer 208. Thereby, highly reliable coupling is obtained more stably.

The magnetic layer that is included in the first magnetization reference layer 209 contributes directly to the MR effect. For example, a Co—Fe—B alloy is used as the first magnetization reference layer 209. Specifically, a (CoₓFe₁₀₀₋ₓ)_{100-y}B_{y} alloy (x being not less than 0 at. % and not more than 100 at. %, and y being not less than 0 at. % and not more than 30 at. %) also may be used as the first magnetization reference layer 209. For example, the fluctuation between the elements caused by crystal grains can be suppressed even in the case where the size of the sensor portion 50A is small by using a (CoₓFe₁₀₀₋ₓ)_{100-y}B_{y} amorphous alloy as the first magnetization reference layer 209.

The layer (e.g., the tunneling insulating layer (not illustrated)) that is formed on the first magnetization reference layer 209 can be planarized. The defect density of the tunneling insulating layer can be reduced by the planarization of the tunneling insulating layer. Thereby, a higher MR ratio is obtained with a lower resistance per area. For example, in the case where MgO is used as the material of the tunneling insulating layer, the (100) orientation of the MgO layer formed on the tunneling insulating layer can be strengthened by using a (CoₓFe₁₀₀₋ₓ)_{100-y}B_{y} amorphous alloy as the first magnetization reference layer 209. A higher MR ratio is obtained by increasing the (100) orientation of the MgO layer. The (CoₓFe₁₀₀₋ₓ)_{100-y}B_{y} alloy crystallizes using the (100) plane of the MgO layer as a template when annealing. Therefore, good crystal conformation between the MgO and the (CoₓFe₁₀₀₋ₓ)_{100-y}B_{y} alloy is obtained. A higher MR ratio is obtained by obtaining good crystal conformation.

Other than the Co—Fe—B alloy, for example, an Fe—Co alloy may be used as the first magnetization reference layer 209.

A higher MR ratio is obtained as the thickness of the first magnetization reference layer 209 increases. For example, a larger fixed magnetic field is obtained as the thickness of the first magnetization reference layer 209 decreases. A trade-off relationship between the MR ratio and the fixed magnetic field exists for the thickness of the first magnetization reference layer 209. In the case where the Co—Fe—B alloy is used as the first magnetization reference layer 209, it is favorable for the thickness of the first magnetization reference layer 209 to be not less than 1.5 nm and not more than 5 nm. It is more favorable for the thickness of the first magnetization reference layer 209 to be not less than 2.0 nm and not more than 4 nm.

Other than the materials described above, the first magnetization reference layer 209 may include a Co₉₀Fe₁₀ alloy having a fcc structure, Co having a hcp structure, or a Co alloy having a hcp structure. For example, at least one selected from the group consisting of Co, Fe, and Ni is used as the first magnetization reference layer 209. An alloy that includes at least one material selected from these materials is used as the first magnetization reference layer 209. For example, a higher MR ratio is obtained by using an FeCo alloy material having a bcc structure, a Co alloy having a cobalt composition of 50% or more, or a material (a Ni alloy) having a Ni composition of 50% or more as the first magnetization reference layer 209.

For example, a Heusler magnetic alloy layer such as Co₂MnGe, Co₂FeGe, Co₂MnSi, Co₂FeSi, Co₂MnAl, Co₂FeAl, Co₂MnGa_{0.5}Ge_{0.5}, Co₂FeGa_{0.5}Ge_{0.5}, etc., also may be used as the first magnetization reference layer 209. For example, a Co₄₀Fe₄₀B₂₀ layer having a thickness of, for example, 3 nm is used as the first magnetization reference layer 209.

For example, the intermediate layer 203 breaks the magnetic coupling between the first magnetization reference layer 209 and the free magnetic layer 210.

For example, the material of the intermediate layer 203 includes a metal, an insulator, or a semiconductor. For example, Cu, Au, Ag, or the like is used as the metal. In the case where a metal is used as the intermediate layer 203, the thickness of the intermediate layer is, for example, not less than about 1 nm and not more than about 7 nm. For example, magnesium oxide (MgO, etc.), aluminum oxide (Al₂O₃, etc.), titanium oxide (TiO, etc.), zinc oxide (ZnO, etc.), gallium oxide (Ga—O), or the like is used as the insulator or the semiconductor. In the case where the insulator or the semiconductor is used as the intermediate layer 203, the thickness of the intermediate layer 203 is, for example, not less than about 0.6 nm and not more than about 2.5 nm. For example, a CCP (Current-Confined-Path) spacer layer may be used as the intermediate layer 203. In the case where a CCP spacer layer is used as the spacer layer, for example, a structure is used in which a copper (Cu) metal path is formed inside an insulating layer of aluminum oxide (Al₂O₃). For example, a MgO layer having a thickness of 1.6 nm is used as the intermediate layer.

The free magnetic layer 210 includes a ferromagnet material. For example, the free magnetic layer 210 includes a ferromagnet material including Fe, Co, and Ni. For example, an FeCo alloy, a NiFe alloy, or the like is used as the material of the free magnetic layer 210. Further, the free magnetic layer 210 includes a Co—Fe—B alloy, an Fe—Co—Si—B alloy, an Fe—Ga alloy having a large λs (magnetostriction constant), an Fe—Co—Ga alloy, a Tb-M-Fe alloy, a Tb-M1-Fe-M2 alloy, an Fe-M3-M4-B alloy, Ni, Fe—Al, ferrite, etc. For example, the λs (the magnetostriction constant) is large for these materials. In the Tb-M-Fe alloy recited above, M is at least one selected from the group consisting of Sm, Eu, Gd, Dy, Ho, and Er. In the Tb-M1-Fe-M2 alloy recited above, M1 is at least one selected from the group consisting of Sm, Eu, Gd, Dy, Ho, and Er. M2 is at least one selected from the group consisting of Ti, Cr, Mn, Co, Cu, Nb, Mo, W, and Ta. In the Fe-M3-M4-B alloy recited above, M3 is at least one selected from the group consisting of Ti, Cr, Mn, Co, Cu, Nb, Mo, W, and Ta. M4 is at least one selected from the group consisting of Ce, Pr, Nd, Sm, Tb, Dy, and Er. Fe₃O₄, (FeCo)₃O₄, etc., are examples of the ferrite recited above. The thickness of the free magnetic layer 210 is, for example, 2 nm or more.

The free magnetic layer 210 may include a magnetic material including boron. The free magnetic layer 210 may include, for example, an alloy including boron (B) and at least one element selected from the group consisting of Fe, Co, and Ni. The free magnetic layer 210 includes, for example, a Co—Fe—B alloy or an Fe—B alloy. For example, a Co₄₀Fe₄₀B₂₀ alloy is used. Ga, Al, Si, W, etc., may be added in the case where the free magnetic layer 210 includes an alloy including boron (B) and at least one element selected from the group consisting of Fe, Co, and Ni. For example, high magnetostriction is promoted by adding these elements. For example, an Fe—Ga—B alloy, an Fe—Co—Ga—B alloy, or an Fe—Co—Si—B alloy may be used as the free magnetic layer 210. By using such a magnetic material including boron, the coercivity (Hc) of the free magnetic layer 210 is low; and the change of the magnetization direction for the strain is easy. Thereby, high sensitivity is obtained.

It is favorable for the boron concentration (e.g., the composition ratio of boron) of the free magnetic layer 210 to be 5 at. % (atomic percent) or more. Thereby, an amorphous structure is easier to obtain. It is favorable for the boron concentration of the free magnetic layer to be 35 at. % or less. For example, the magnetostriction constant decreases when the boron concentration is too high. For example, it is favorable for the boron concentration of the free magnetic layer to be not less than 5 at. % and not more than 35 at. %; and it is more favorable to be not less than 10 at. % and not more than 30 at. %.

In the case where a portion of the magnetic layer of the free magnetic layer 210 includes Fe_{1-y}B_{y} (0<y≤0.3) or (Fe_{z}X_{1-z})_{1-y}B_{y} (X being Co or Ni, 0.8≤z<1, and 0<y≤0.3), it is easy to realize both a large magnetostriction constant λ and a low coercivity. Therefore, this is particularly favorable from the perspective of obtaining a high gauge factor. For example, Fe₈₀B₂₀ (4 nm) is used as the free magnetic layer 210. Co₄₀Fe₄₀B₂₀ (0.5 nm)/Fe₈₀B₂₀ (4 nm) is used as the free magnetic layer.

The free magnetic layer 210 may have a multilayered structure. In the case where a tunneling insulating layer of MgO is used as the intermediate layer 203, it is favorable to provide a layer of a Co—Fe—B alloy at the portion of the free magnetic layer 210 contacting the intermediate layer 203. Thereby, a high magnetoresistance effect is obtained. In such a case, a layer of a Co—Fe—B alloy is provided on the intermediate layer 203; and another magnetic material that has a large magnetostriction constant is provided on the layer of the Co—Fe—B alloy. In the case where the free magnetic layer 210 has the multilayered structure, for example, the free magnetic layer 210 includes Co—Fe—B (2 nm)/Fe—Co—Si—B (4 nm), etc.

The capping layer 211 protects the layers provided under the capping layer 211. The capping layer 211 includes, for example, multiple metal layers. The capping layer 211 includes, for example, a two-layer structure (Ta/Ru) of a Ta layer and a Ru layer. The thickness of the Ta layer is, for example, 1 nm; and the thickness of the Ru layer is, for example, 5 nm. As the capping layer 211, another metal layer may be provided instead of the Ta layer and/or the Ru layer. The configuration of the capping layer 211 is arbitrary. For example, a nonmagnetic material is used as the capping layer 211. Another material may be used as the capping layer 211 as long as the material can protect the layers provided under the capping layer 211.

In the case where the free magnetic layer 210 includes a magnetic material including boron, a diffusion suppression layer (not illustrated) of an oxide material and/or a nitride material may be provided between the free magnetic layer 210 and the capping layer 211. Thereby, for example, the diffusion of boron is suppressed. By using the diffusion suppression layer including an oxide layer or a nitride layer, the diffusion of the boron included in the free magnetic layer 210 can be suppressed; and the amorphous structure of the free magnetic layer 210 can be maintained. As the oxide material and/or the nitride material included in the diffusion suppression layer, for example, an oxide material or a nitride material including an element such as Mg, Al, Si, Ti, V, Cr, Mn, Fe, Co, Ni, Cu, Zn, Zr, Nb, Mo, Ru, Rh, Pd, Ag, Hf, Ta, W, Sn, Cd, Ga, or the like is used. The diffusion suppression layer is a layer that does not contribute to the magnetoresistance effect. It is favorable for the resistance per area of the diffusion suppression layer to be low. For example, it is favorable for the resistance per area of the diffusion suppression layer to be set to be lower than the resistance per area of the intermediate layer that contributes to the magnetoresistance effect. From the perspective of reducing the resistance per area of the diffusion suppression layer, it is favorable for the diffusion suppression layer to be an oxide or a nitride of Mg, Ti, V, Zn, Sn, Cd, and Ga. The barrier height is low for these materials. It is favorable to use an oxide having a stronger chemical bond to suppress the diffusion of boron. For example, a MgO layer of 1.5 nm is used. Oxynitrides are included in one of the oxide or the nitride.

In the case where the diffusion suppression layer includes an oxide or a nitride, it is favorable for the thickness of the diffusion suppression layer to be, for example, 0.5 nm or more. Thereby, the diffusion suppression function of the boron is realized sufficiently. It is favorable for the thickness of the diffusion suppression layer to be 5 nm or less. Thereby, for example, a low resistance per area is obtained. It is favorable for the thickness of the diffusion suppression layer to be not less than 0.5 nm and not more than 5 nm; and it is favorable to be not less than 1 nm and not more than 3 nm.

At least one selected from the group consisting of magnesium (Mg), silicon (Si), and aluminum (Al) may be used as the diffusion suppression layer. A material that includes these light elements is used as the diffusion suppression layer. These light elements produce compounds by bonding with boron. For example, at least one of a Mg—B compound, an Al—B compound, or a Si—B compound is formed at the portion including the interface between the diffusion suppression layer and the free magnetic layer 210. These compounds suppress the diffusion of boron.

Another metal layer, etc., may be inserted between the diffusion suppression layer and the free magnetic layer 210. In the case where the distance between the diffusion suppression layer and the free magnetic layer 210 is too long, boron diffuses between the diffusion suppression layer and the free magnetic layer 210; and the boron concentration in the free magnetic layer 210 undesirably decreases. Therefore, it is favorable for the distance between the diffusion suppression layer and the free magnetic layer 210 to be 10 nm or less; and it is more favorable to be 3 nm or less.

FIG. 8 is a schematic perspective view illustrating a portion of another sensor according to the embodiment.

As shown in FIG. 8, other than an insulating layer 213 being provided, the sensor portion 50AA is similar to the sensor portion 50A. The insulating layer 213 is provided between the lower electrode 204 and the upper electrode 212. The insulating layer 213 is arranged with the free magnetic layer 210 and the first magnetization reference layer 209 in a direction crossing the direction connecting the lower electrode 204 and the upper electrode 212. Portions other than the insulating layer 213 are similar to those of the sensor portion 50A; and a description is therefore omitted.

The insulating layer 213 includes, for example, aluminum oxide (e.g., Al₂O₃), silicon oxide (e.g., SiO₂), etc. The leakage current of the sensor portion 50AA is suppressed by the insulating layer 213. The insulating layer 213 may be provided in the sensor portions described below.

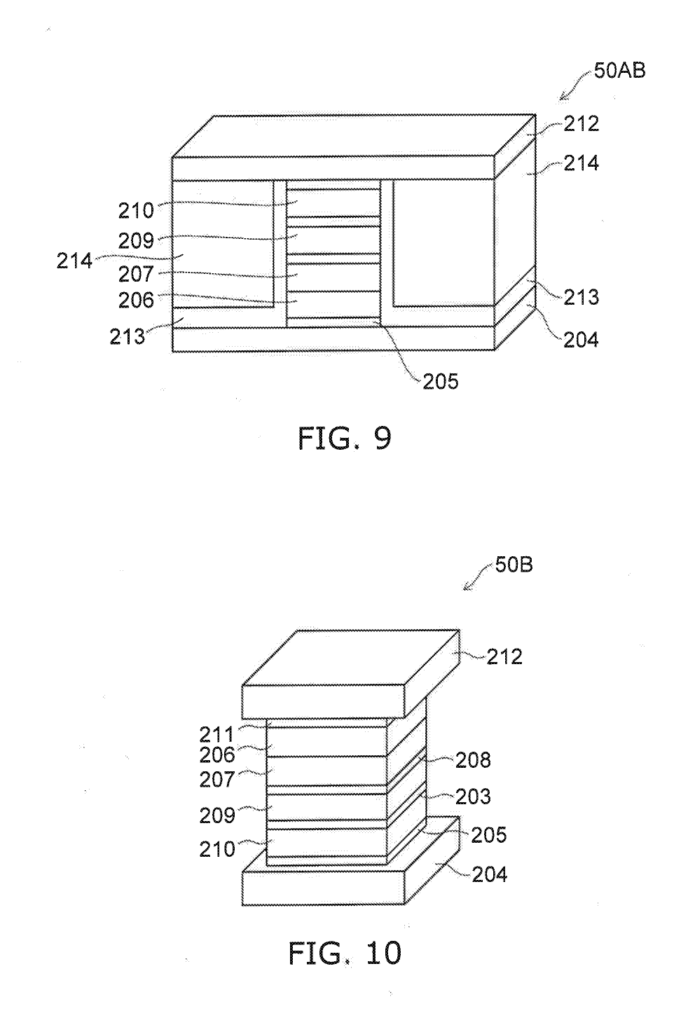

FIG. 9 is a schematic perspective view illustrating a portion of another sensor according to the embodiment.

As shown in FIG. 9, a hard bias layer 214 is further provided in the sensor portion 50AB. Otherwise, the sensor portion 50AB is similar to the sensor portion 50A. The hard bias layer 214 is provided between the lower electrode 204 and the upper electrode 212. The free magnetic layer 210 and the first magnetization reference layer 209 are provided between two portions of the hard bias layer 214 in a direction crossing the direction connecting the lower electrode 204 and the upper electrode 212. Otherwise, the sensor portion 50AB is similar to the sensor portion 50AA.

The hard bias layer 214 sets the magnetization direction of the free magnetic layer 210 by the magnetization of the hard bias layer 214. The magnetization direction of the free magnetic layer 210 is set to the desired direction by the hard bias layer 214 in a state in which pressure from the outside is not applied to the film.

The hard bias layer 214 includes, for example, Co—Pt, Fe—Pt, Co—Pd, Fe—Pd, etc. For example, the magnetic anisotropy and the coercivity are relatively high for these materials. These materials are, for example, hard magnetic materials. The hard bias layer 214 may include, for example, an alloy in which an added element is further added to Co—Pt, Fe—Pt, Co—Pd, or Fe—Pd. The hard bias layer 214 may include, for example, CoPt (the proportion of Co being not less than 50 at. % and not more than 85 at. %), (CoₓPt₁₀₀₋ₓ)_{10000-y}Cr_{y} (x being not less than 50 at. % and not more than 85 at. %, and y being not less than 0 at. % and not more than 40 at. %), FePt (the proportion of Pt being not less than 40 at. % and not more than 60 at. %), etc. In the case where such a material is used, the direction of the magnetization of the hard bias layer 214 is set (fixed) to the direction in which the external magnetic field is applied by applying an external magnetic field that is larger than the coercivity of the hard bias layer 214. The thickness of the hard bias layer 214 (e.g., the length along the direction from the lower electrode 204 toward the upper electrode) is, for example, not less than 5 nm and not more than 50 nm.

In the case where the insulating layer 213 is provided between the lower electrode 204 and the upper electrode 212, SiOₓ or AlOₓ is used as the material of the insulating layer 213. A not-illustrated foundation layer may be further provided between the insulating layer 213 and the hard bias layer 214. Cr, Fe—Co, or the like is used as the material of the foundation layer for the hard bias layer 214 in the case where the hard bias layer 214 includes a hard magnetic material such as Co—Pt, Fe—Pt, Co—Pd, Fe—Pd, etc.

The hard bias layer 214 may have a structure in which a not-illustrated hard bias-layer pinning layer is stacked. In such a case, the direction of the magnetization of the hard bias layer 214 can be set (fixed) by the exchange coupling of the hard bias layer 214 and the hard bias-layer pinning layer. In such a case, the hard bias layer 214 includes a ferromagnetic material of at least one selected from the group consisting of Fe, Co, and Ni, or an alloy including at least one type of these elements. In such a case, the hard bias layer 214 includes, for example, a CoₓFe₁₀₀₋ₓ alloy (x being not less than 0 at. % and not more than 100 at. %), a NiₓFe₁₀₀₋ₓ alloy (x being not less than 0 at. % and not more than 100 at. %), or a material in which a nonmagnetic element is added to these alloys. A material similar to the first magnetization reference layer 209 recited above is used as the hard bias layer 214. The hard bias-layer pinning layer includes a material similar to the pinning layer 206 inside the sensor portion 50A recited above. In the case where the hard bias-layer pinning layer is provided, a foundation layer similar to the material included in the foundation layer 205 may be provided under the hard bias-layer pinning layer. The hard bias-layer pinning layer may be provided at the lower portion or the upper portion of the hard bias layer. In such a case, the magnetization direction of the hard bias layer 214 is determined by heat treatment in a magnetic field similarly to the pinning layer 206.

The hard bias layer 214 and the insulating layer 213 recited above are applicable also to any sensor portion according to the embodiment. By using the stacked structure of the hard bias layer 214 and the hard bias-layer pinning layer, the orientation of the magnetization of the hard bias layer 214 can be maintained easily even in the case where a large external magnetic field is applied to the hard bias layer 214 in a short length of time.

FIG. 10 is a schematic perspective view illustrating a portion of another sensor according to the embodiment.

In the sensor portion 50B as shown in FIG. 10, the lower electrode 204, the foundation layer 205, the free magnetic layer 210, the intermediate layer 203, the first magnetization reference layer 209, the magnetic coupling layer 208, the second magnetization reference layer 207, the pinning layer 206, the capping layer 211, and the upper electrode 212 are stacked in order. The sensor portion 50B is, for example, a top spin-valve type.

The foundation layer 205 includes, for example, a stacked film of tantalum and copper (Ta/Cu). The thickness (the length in the Z-axis direction) of the Ta layer is, for example, 3 nm. The thickness of the Cu layer is, for example, 5 nm. The free magnetic layer 210 includes, for example, Co₄₀Fe₄₀B₂₀ having a thickness of 4 nm. The intermediate layer 203 includes, for example, a MgO layer having a thickness of 1.6 nm. The first magnetization reference layer 209 includes, for example, Co₄₀Fe₄₀B₂₀/Fe₅₀Co₅₀. The thickness of the Co₄₀Fe₄₀B₂₀ layer is, for example, 2 nm. The thickness of the Fe₅₀Co₅₀ layer is, for example, 1 nm. The magnetic coupling layer 208 includes, for example, a Ru layer having a thickness of 0.9 nm. The second magnetization reference layer 207 includes, for example, a Co₇₅Fe₂₅ layer having a thickness of 2.5 nm. The pinning layer 206 includes, for example, an IrMn-layer having a thickness of 7 nm. The capping layer 211 includes, for example, Ta/Ru. The thickness of the Ta layer is, for example, 1 nm. The thickness of the Ru layer is, for example, 5 nm.

The materials of the layers included in the sensor portion 50B may be the vertically inverted materials of the layers included in the sensor portion 50A. The diffusion suppression layer recited above may be provided between the foundation layer 205 and the free magnetic layer 210 of the sensor portion 50B.

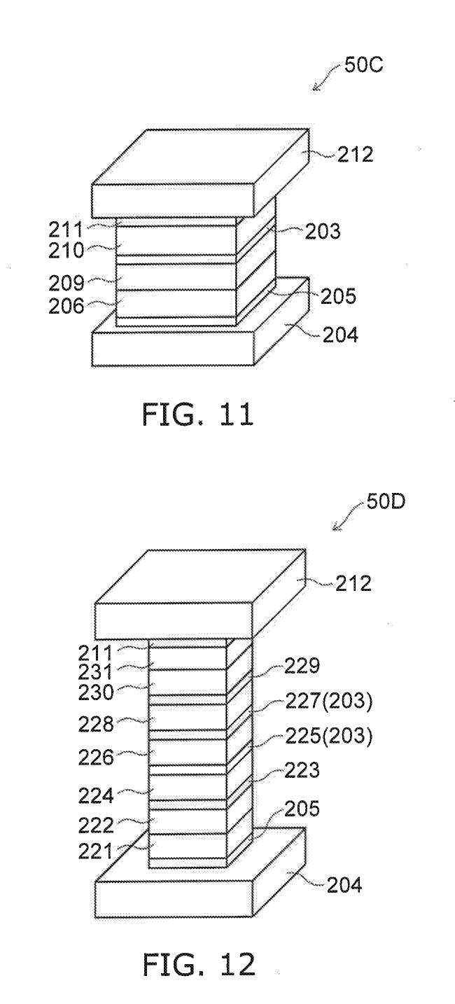

FIG. 11 is a schematic perspective view illustrating a portion of another sensor according to the embodiment.

In the sensor portion 50C as shown in FIG. 11, the lower electrode 204, the foundation layer 205, the pinning layer 206, the first magnetization reference layer 209, the intermediate layer 203, the free magnetic layer 210, and the capping layer 211 are stacked in this order. For example, the sensor portion 50C has a single pinned structure that uses a single magnetization reference layer.

The foundation layer 205 includes, for example, Ta/Ru. The thickness (the length in the Z-axis direction) of the Ta layer is, for example, 3 nm. The thickness of the Ru layer is, for example, 2 nm. The pinning layer 206 includes, for example, an IrMn-layer having a thickness of 7 nm. The first magnetization reference layer 209 includes, for example, a Co₄₀Fe₄₀B₂₀ layer having a thickness of 3 nm. The intermediate layer 203 includes, for example, a MgO layer having a thickness of 1.6 nm. The free magnetic layer 210 includes, for example, Co₄₀Fe₄₀B₂₀ having a thickness of 4 nm. The capping layer 211 includes, for example, Ta/Ru. The thickness of the Ta layer is, for example, 1 nm. The thickness of the Ru layer is, for example, 5 nm.

For example, materials similar to the materials of the layers of the sensor portion 50A are used as the materials of the layers of the sensor portion 50C.

FIG. 12 is a schematic perspective view illustrating a portion of another sensor according to the embodiment.

In the sensor portion 50D as shown in FIG. 12, the lower electrode 204, the foundation layer 205, a lower pinning layer 221, a lower second magnetization reference layer 222, a lower magnetic coupling layer 223, a lower first magnetization reference layer 224, a lower intermediate layer 225, a free magnetic layer 226, an upper intermediate layer 227, an upper first magnetization reference layer 228, an upper magnetic coupling layer 229, an upper second magnetization reference layer 230, an upper pinning layer 231, and the capping layer 211 are stacked in order.

The foundation layer 205 includes, for example, Ta/Ru. The thickness (the length in the Z-axis direction) of the Ta layer is, for example, 3 nanometers (nm). The thickness of the Ru layer is, for example, 2 nm. The lower pinning layer 221 includes, for example, an IrMn-layer having a thickness of 7 nm. The lower second magnetization reference layer 222 includes, for example, a Co₇₅Fe₂₅ layer having a thickness of 2.5 nm. The lower magnetic coupling layer 223 includes, for example, a Ru layer having a thickness of 0.9 nm. The lower first magnetization reference layer 224 includes, for example, a Co₄₀Fe₄₀B₂₀ layer having a thickness of 3 nm. The lower intermediate layer 225 includes, for example, a MgO layer having a thickness of 1.6 nm. The free magnetic layer 226 includes, for example, Co₄₀Fe₄₀B₂₀ having a thickness of 4 nm. The upper intermediate layer 227 includes, for example, a MgO layer having a thickness of 1.6 nm. The upper first magnetization reference layer 228 includes, for example, Co₄₀Fe₄₀B₂₀/Fe₅₀Co₅₀. The thickness of the Co₄₀Fe₄₀B₂₀ layer is, for example, 2 nm. The thickness of the Fe₅₀Co₅₀ layer is, for example, 1 nm. The upper magnetic coupling layer 229 includes, for example, a Ru layer having a thickness of 0.9 nm. The upper second magnetization reference layer 230 includes, for example, a Co₇₅Fe₂₅ layer having a thickness of 2.5 nm. The upper pinning layer 231 includes, for example, an IrMn-layer having a thickness of 7 nm. The capping layer 211 includes, for example, Ta/Ru. The thickness of the Ta layer is, for example, 1 nm. The thickness of the Ru layer is, for example, 5 nm.

For example, materials similar to the materials of the layers of the sensor portion 50A are used as the materials of the layers of the sensor portion 50D.

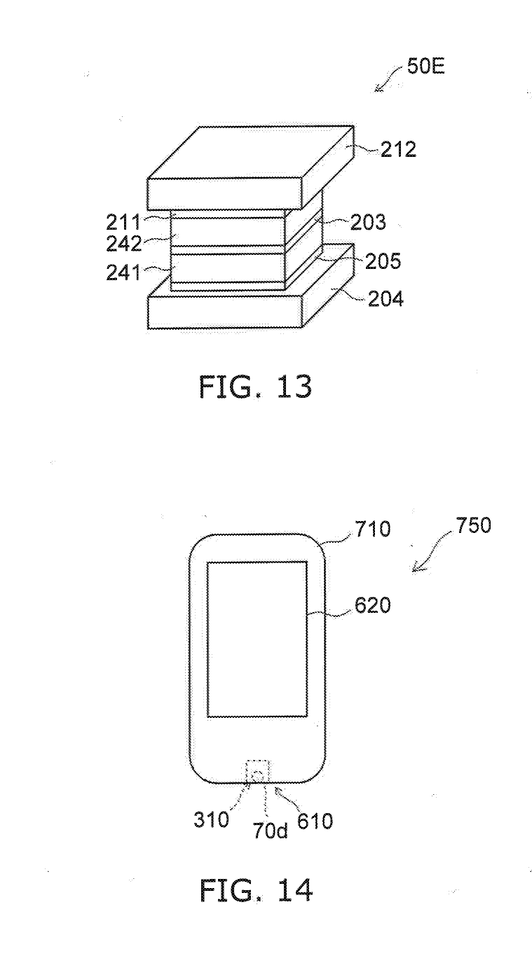

FIG. 13 is a schematic perspective view illustrating a portion of another sensor according to the embodiment.

In the sensor portion 50E as shown in FIG. 13, the lower electrode 204, the foundation layer 205, a first free magnetic layer 241, the intermediate layer 203, a second free magnetic layer 242, the capping layer 211, and the upper electrode 212 are stacked in this order.

The foundation layer 205 includes, for example, Ta/Cu. The thickness (the length in the Z-axis direction) of the Ta layer is, for example, 3 nm. The thickness of the Cu layer is, for example, 5 nm. The first free magnetic layer 241 includes, for example, Co₄₀Fe₄₀B₂₀ having a thickness of 4 nm. The intermediate layer 203 includes, for example, Co₄₀Fe₄₀B₂₀ having a thickness of 4 nm. The capping layer 211 includes, for example, Cu/Ta/Ru. The thickness of the Cu layer is, for example, 5 nm. The thickness of the Ta layer is, for example, 1 nm. The thickness of the Ru layer is, for example, 5 nm.

Materials similar to the materials of the layers of the sensor portion 50A are used as the materials of the layers of the sensor portion 50E. For example, materials similar to those of the free magnetic layer 210 of the sensor portion 50A may be used as the materials of the first free magnetic layer 241 and the second free magnetic layer 242.

### Second Embodiment

The embodiment relates to an electronic device. The electronic device includes, for example, a sensor or a modification of a sensor according to the embodiment recited above. The electronic device includes, for example, an information terminal. The information terminal includes a recorder, etc. The electronic device includes a microphone, a blood pressure sensor, a touch panel, etc.

FIG. 14 is a schematic view illustrating the electronic device according to the second embodiment.

As shown in FIG. 14, the electronic device 750 according to the embodiment is, for example, an information terminal 710. For example, a microphone 610 is provided in the information terminal 710.

The microphone 610 includes, for example, a sensor 310. For example, the first film 40 is substantially parallel to the surface where a displayer 620 of the information terminal 710 is provided. The arrangement of the first film 40 is arbitrary. Any sensor described in reference to the first embodiment is applied to the sensor 310.

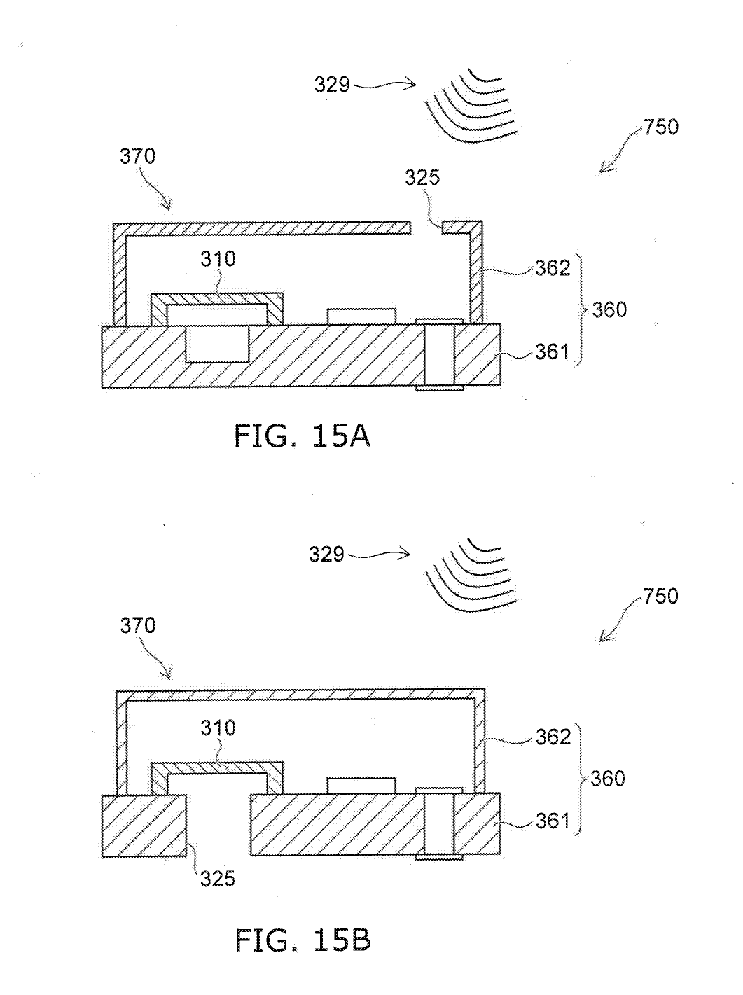

FIG. 15A and FIG. 15B are schematic cross-sectional views illustrating the electronic device according to the second embodiment.

As shown in FIG. 15A and FIG. 15B, the electronic device 750 (e.g., a microphone 370 (an acoustic microphone)) includes a housing 360 and the sensor 310. The housing 360 includes, for example, a substrate 361 (e.g., a printed circuit board) and a cover 362. The substrate 361 includes, for example, a circuit such as an amplifier, etc.

An acoustic hole 325 is provided in the housing 360 (at least one of the substrate 361 or the cover 362). In the example shown in FIG. 15B, the acoustic hole 325 is provided in the cover 362. In the example shown in FIG. 15B, the acoustic hole 325 is provided in the substrate 361. Sound 329 enters the interior of the cover 362 via the acoustic hole 325. The microphone 370 responds to the sound pressure.

For example, the sensor 310 is placed on the substrate 361; and an electrical signal line (not illustrated) is provided. The cover 362 is provided to cover the sensor 310. The housing 360 is provided around the sensor 310. At least a portion of the sensor 310 is provided inside the housing 360. For example, the first sensor portion 51 and the first film 40 are provided between the substrate 361 and the cover 362. For example, the sensor 310 is provided between the substrate 361 and the cover 362.

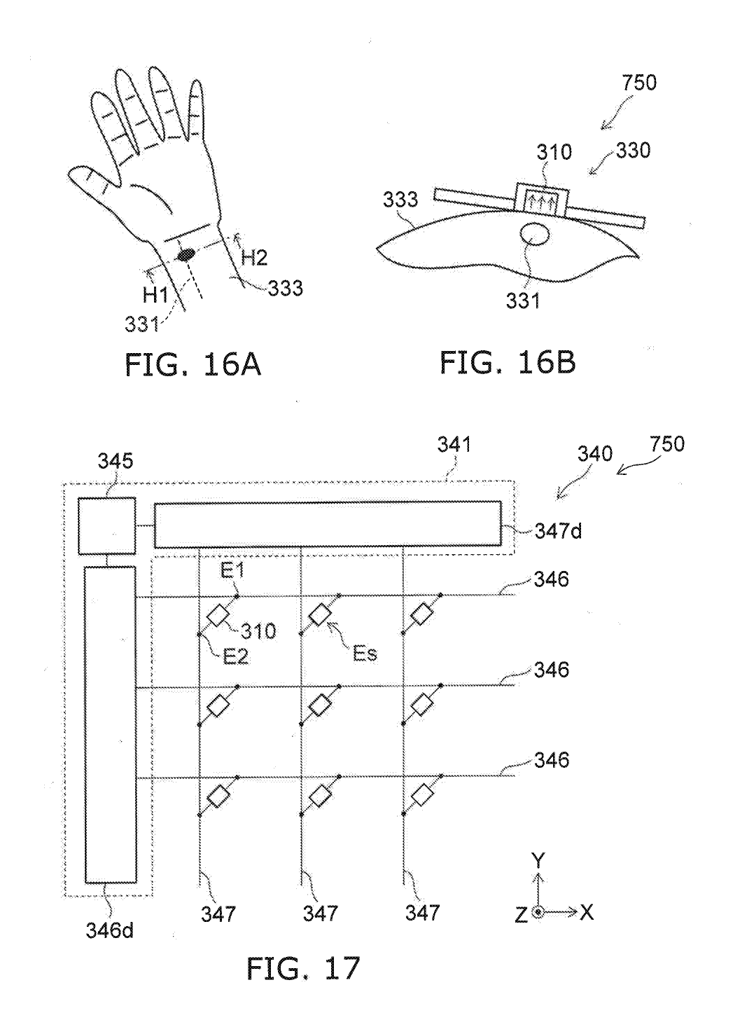

FIG. 16A and FIG. 16B are schematic views illustrating another electronic device according to the second embodiment.

In the example of these drawings, the electronic device 750 is a blood pressure sensor 330. FIG. 16A is a schematic plan view illustrating skin on an arterial vessel of a human. FIG. 16B is a line H1-H2 cross-sectional view of FIG. 16A.

The sensor 310 is used as the sensor of the blood pressure sensor 330. The sensor 310 contacts the skin 333 on the arterial vessel 331. Thereby, the blood pressure sensor 330 can continuously perform blood pressure measurements.

FIG. 17 is a schematic view illustrating another electronic device according to the second embodiment.

In the example of the drawing, the electronic device 750 is a touch panel 340. In the touch panel 340, the sensors 310 are provided in at least one of the interior of the display or the exterior of the display.

For example, the touch panel 340 includes multiple first interconnects 346, multiple second interconnects 347, the multiple sensors 310, and a control circuit 341.

In the example, the multiple first interconnects 346 are arranged along the Y-axis direction. Each of the multiple first interconnects 346 extends along the X-axis direction. The multiple second interconnects 347 are arranged along the X-axis direction. Each of the multiple second interconnects 347 extends along the Y-axis direction.

One of the multiple sensors 310 is provided at the crossing portion between the multiple first interconnects 346 and the multiple second interconnects 347. One of the sensors 310 is used as one of sensing components Es for sensing. The crossing portion includes the position where the first interconnect 346 and the second interconnect 347 cross and includes the region at the periphery of the position.

One end E1 of one of the multiple sensors 310 is connected to one of the multiple first interconnects 346. Another end E2 of the one of the multiple sensors 310 is connected to one of the multiple second interconnects 347.

The control circuit 341 is connected to the multiple first interconnects 346 and the multiple second interconnects 347. For example, the control circuit 341 includes a first interconnect circuit 346d that is connected to the multiple first interconnects 346, a second interconnect circuit 347d that is connected to the multiple second interconnects 347, and a control signal circuit 345 that is connected to the first interconnect circuit 346d and the second interconnect circuit 347d.

According to the second embodiment, an electronic device that uses a sensor in which the sensitivity can be increased can be provided.

According to the embodiments, a sensor and an electronic device are provided in which the sensing precision can be increased.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the invention is not limited to these specific examples. For example, one skilled in the art may similarly practice the invention by appropriately selecting specific configurations of components such as the first film, the first sensor portion, the first to fourth terminals, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all sensors and electronic devices practicable by an appropriate design modification by one skilled in the art based on the sensors and the electronic devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A sensor, comprising:
a first film including a first electrode layer, a second electrode layer, and a piezoelectric layer provided between the first electrode layer and the second electrode layer, the first film being deformable;
a first sensor portion fixed to a portion of the first film, a first direction from the portion of the first film toward the first sensor portion being aligned with a direction from the second electrode layer toward the first electrode layer, the first sensor portion including a first sensor conductive layer, a second sensor conductive layer, a first magnetic layer provided between the first sensor conductive layer and the second sensor conductive layer, a second magnetic layer provided between the first magnetic layer and the second sensor conductive layer, and a first intermediate layer provided between the first magnetic layer and the second magnetic layer;
a first terminal electrically connected to the first electrode layer;
a second terminal electrically connected to the second electrode layer;
a third terminal electrically connected to the first sensor conductive layer; and
a fourth terminal electrically connected to the second sensor conductive layer.

2. A sensor, comprising:
a first film including a first electrode layer, a second electrode layer, and a piezoelectric layer provided between the first electrode layer and the second electrode layer, the first film being deformable;
a first sensor portion fixed to a portion of the first film, a first direction from the portion of the first film toward the first sensor portion being aligned with a direction from the second electrode layer toward the first electrode layer, the first sensor portion including a first sensor conductive layer, a second sensor conductive layer, a first magnetic layer provided between the first sensor conductive layer and the second sensor conductive layer, a second magnetic layer provided between the first magnetic layer and the second sensor conductive layer, and a first intermediate layer provided between the first magnetic layer and the second magnetic layer;
a first terminal electrically connected to the first electrode layer and the second sensor conductive layer;
a second terminal electrically connected to the second electrode layer; and
a third terminal electrically connected to the first sensor conductive layer.

3. The sensor according to claim 1, wherein a band of a frequency of a sensing object is modifiable.

4. The sensor according to claim 1, further comprising a supporter supporting the first film,
the piezoelectric layer including:
a first region, a direction from the supporter toward the first region being along the first direction; and
a second region continuous with the first region, a direction from the supporter toward the second region crossing the first direction,
the second region including the portion of the first film.

5. The sensor according to claim 4, wherein
the supporter includes a first portion and a second portion,
a second direction from the first portion toward the second portion crosses the first direction,
the piezoelectric layer further includes a third region continuous with the second region,
a direction from the first portion toward the first region being along the first direction, and
a direction from the second portion toward the third region being along the first direction.

6. The sensor according to claim 1, wherein a thickness along the first direction of the piezoelectric layer is not less than 0.5 times a length along the first direction of the first film.

7. The sensor according to claim 1, wherein
the first film further includes a first layer,
the first layer is provided at one of a first position or a second position,
the first electrode layer is between the first position and the second electrode layer in the first direction,
the second electrode layer is between the second position and the first electrode layer in the first direction, and
a center of the first film in the first direction is provided between the first electrode layer and the second electrode layer in the first direction.

8. The sensor according to claim 7, wherein
the first film further includes a second layer, and
the second layer is provided at the other of the first position or the second position.

9. The sensor according to claim 1, wherein
the first film has a first surface and a second surface,
a direction from the first surface toward the second surface is aligned with the first direction,
the first surface contacts at least one of a gas or a liquid, and
the second surface contacts at least one of a gas or a liquid.

10. The sensor according to claim 1, wherein a first resonant frequency of the first film in a first state is different from a second resonant frequency of the first film in a second state, a potential difference between the first terminal and the second terminal in the first state being a first value, the potential difference in the second state being a second value different from the first value.

11. The sensor according to claim 10, wherein
a first frequency of a change of an electrical resistance between the first magnetic layer and the second magnetic layer in the first state is lower than the first resonant frequency, and
a second frequency of a change of the electrical resistance in the second state is lower than the second resonant frequency.

12. The sensor according to claim 10, further comprising a controller electrically connected to the first terminal and the second terminal,
the controller executing a first control in a first interval of setting the potential difference to the first value, and executing a second control in a second interval of setting the potential difference to the second value, the second value being different from the first value, the second interval being different from the first interval.

13. The sensor according to claim 12, wherein
the controller acquires a first signal relating to a change of an electrical resistance between the first magnetic layer and the second magnetic layer in the first state, acquires a second signal relating to a change of the electrical resistance in the second state, outputs a first output signal including a first component of the first signal, and outputs a second output signal including a second component of the second signal,
a first frequency of the first component is lower than the first resonant frequency, and
a second frequency of the second component is not less than the first resonant frequency but lower than the second resonant frequency.

14. The sensor according to claim 12, wherein
the controller acquires a first signal relating to a change of an electrical resistance between the first magnetic layer and the second magnetic layer in the first state, acquires a second signal relating to a change of the electrical resistance in the second state, and outputs a first output signal based on the first signal and a second output signal based on the second signal, and
at least one of the first output signal or the second output signal is based on a sensitivity of the change of the electrical resistance in the first state and a sensitivity of the change of the electrical resistance in the second state.

15. The sensor according to claim 10, wherein the second resonant frequency is not less than 5 times the first resonant frequency.

16. The sensor according to claim 1, further comprising:
a substrate; and
a cover,
the first sensor portion and the first film being provided between the substrate and the cover.

17. An electronic device, comprising:
the sensor according to claim 1; and
a housing.
